(19) United States
(12) Patent Application Publication
(10) Pub. No.: US 2015/0060267 A1
(43) Pub. Date: Mar. 5, 2015

(54) DIAMOND ELECTRODES FOR ELECTROCHEMICAL DEVICES

(71) Applicant: Helen Wilman, (US)

(72) Inventors: Timothy Peter Mollart, Ascot (GB); John Robert Brandon, Ascot (GB); Jonathan James Wilman, Ascot (GB)

(73) Assignee: ELEMENT SIX LIMITED, Ballasalla (IM)

(21) Appl. No.: 13/821,960

(22) PCT Filed: Sep. 8, 2011
(86) PCT No.: PCT/EP2011/065574

§ 371 Date: Sep. 23, 2014

(30) Foreign Application Priority Data
Sep. 14, 2010 (GB) 1015270.0

(51) Int. Cl. C02F 1/461; C23C 16/28; C23C 16/56; C25D 17/10; C25B 11/12

(52) U.S. Cl. CPC C02F 1/46109; C25D 17/10; C25B 11/12; C23C 16/56; C23C 16/28; C02F 2001/46133; C02F 2201/46105
USPC 204/294; 427/113; 216/17

(57) ABSTRACT

A bulk boron doped diamond electrode comprising a plurality of grooves disposed in a surface of the bulk boron doped diamond electrode. The bulk boron doped diamond electrode is formed by growing a bulk boron doped diamond electrode using a chemical vapour deposition technique and forming a plurality of grooves in a surface of the bulk boron doped diamond electrode. According to one arrangement, the plurality of grooves are formed by forming a pattern of carbon solvent metal over a surface of the bulk boron doped diamond electrode and heating whereby the carbon solvent metal dissolves underlying diamond to form grooves in the surface of the bulk boron doped electrode. The invention also relates to an electrochemical cell comprising one or more grooved bulk boron doped diamond electrodes. The or each bulk boron doped diamond electrode is oriented within the electrochemical device such that the grooves are aligned in a direction substantially parallel to a direction of electrolyte flow.

### FIELD OF INVENTION

The present invention relates to the manufacture of diamond electrodes and the use of these electrodes in electrochemical devices.

### BACKGROUND OF INVENTION

It is known that diamond can be doped to make it conductive and that such doped diamond materials can be used to form electrodes for use in electrochemical devices. Diamond-based electrochemical devices have a potentially wide range of applications that include hygiene and waste water treatment and analysis.

The impressive material properties of diamond make it the material of choice for the most challenging electrochemical processes and environments. Its electric conductivity, chemical inertness and, in particular, its wide electrochemical window, make it possible for a diamond device to detect chemical species that previously would not be detected or affected by other materials. When used as an electrochemical cell to treat water the diamond cell can be used to generate extremely powerful oxidants that oxidize any toxic organic matter.

For example, diamond can achieve the direct oxidation of a number of specific organic species, something that would be impossible with titanium, platinum or other noble metal based electrodes. Furthermore, diamond is chemically inert, mechanically robust, non-fouling and non-porous. These qualities extend the lifetime of electrochemical devices and allow them to operate under even the harshest of conditions.

Two general types of diamond electrode are known: diamond coated electrodes which comprises a non-diamond core material over which a coating of diamond is disposed; and solid diamond electrodes which essentially consist of a solid piece of doped diamond material. The later are often referred to as bulk boron doped diamond electrodes (or bulk BDD electrodes). While such bulk boron doped diamond electrodes can be more expensive to manufacture than their coated counterparts, they have a longer lifetime and more stable operating characteristic which make them the preferred option for many applications. For example, the diamond coating on a coated diamond electrode can have a tendency to peel off the underlying core material reducing the reactive surface area of the diamond, allowing adverse reactions to occur on exposed surfaces of the core material, and generally reducing lifetime. Bulk boron doped diamond electrodes offer vastly superior dimensional stability than coated electrodes at electrochemical potentials>2.0 V versus a Standard Calomel Electrode (SCE), thus delivering the capability of sustaining high current densities for extended periods.

Most electrolytes are low conductivity and many applications involve reactions that are limited by mass transport to the electrode surface and hence require large surface area electrodes.

One possibility to increase the surface area of bulk BBD electrodes is to merely increase their size. However, this approach leads to an increase in cost as more diamond material is required and the electrodes take longer to manufacture.

Another approach would be to increase the surface to volume ratio by making the electrodes thinner. One problem with making large thin bulk BBD electrodes is that the electrodes progressively become more fragile and brittle. While diamond is inherently very hard, it has a relatively low toughness and thus large thin electrodes can be prone to cracking and failure if subjected to stress, for example, during post synthesis handling and electrochemical device manufacture. Furthermore, stresses are imparted on the electrodes within an electrochemical device during operation caused, for example, by the flow of electrolyte or solid material impacting on the surface of the electrodes.

Accordingly, the present inventors have identified the need for a robust, low cost, bulk BDD electrode with increased surface area.

One possibility for meeting this need is to treat the surface of a bulk BDD electrode to increase its surface area. Imparting structure to the surface of diamond material is known. For example, Takasu et al. have proposed the use of metal nanoparticles to form nanochannels in the surface of diamond (Y. Takasu, S. Konishi, W. Sugimoto, and Y. Murakami “Catalytic Formation of Nanochannels in the Surface Layers of Diamonds by Metal Nanoparticles” Electrochem. Solid State Lett., 9(7):C114-C177, July 2006).

While the aforementioned approaches have exhibited enhanced electrochemical activity, the present inventors have identified a problem with these approaches. In particular, the present inventors have identified that at high current densities (>500 Am⁻²) the electrodes can lose efficiency.

It is an aim of certain embodiments of the present invention to provide bulk boron doped diamond electrodes with improved electrical efficiency for use in electrochemical devices. In particular, it is an aim of certain embodiments to at least partially solve the aforementioned problem of efficiency drop off during operation in an electrochemical device, particularly at high current densities.

### SUMMARY OF INVENTION

The present inventors have traced the aforementioned problem to gases being trapped in surface structures on the diamond electrodes thus reducing the effective area of the electrodes during operation, particularly at high current densities. In a BDD electrochemical reactor, gases being evolved at the surface of the electrodes, unless allowed to escape efficiently, reduce the effective area of the electrodes. While pits/blind via structures increase the surface area of the electrodes and thus initially enhance electrochemical activity, during operation gases evolved at the electrode surfaces become trapped in the surface structures thus reducing the surface area available for reactions and thus leading to an efficiency drop off due to gas evolution and electrolyte displacement by attached bubbles.

The aforementioned problem could be solved by treating the surface of the electrode so as to remove surface structures which tend to trap and hold gas bubbles on the surface. However, this would lead to a reduction in the overall surface area of the diamond electrodes and thus reduce efficiency. Accordingly, the skilled person is faced with a problem: how does one increase the surface area of the bulk BDD electrodes while simultaneously reducing the tendency of gas bubbles to adhere to the surface of the electrodes?

The present inventors have solved the aforementioned problem by providing a bulk BDD electrode comprising a plurality of grooves disposed in a surface of the bulk BDD electrode, wherein the plurality of grooves are arranged in a pattern, wherein each groove forms a continuous channel, and wherein each groove has a width in the range 1 μm to 1 mm and a depth in the range 1 μm to 1 mm.

The grooves/channels increase the surface area of the bulk BDD electrode. Furthermore, in use, the grooves can be aligned relative to the direction of electrolyte flow so as to enhance fluid flow within the channels/grooves by reducing the boundary layer and/or removing any bubbles attached to the surface of the electrode. In the context of the present invention, a groove may be defined as a continuous channel which can be aligned relative to the direction of electrolyte flow.

The grooved bulk boron doped diamond electrodes may be manufactured using a method comprising: growing a bulk boron doped diamond electrode using a chemical vapour deposition technique; and forming a plurality of grooves in a surface of the bulk boron doped diamond electrode. The plurality of grooves may be formed during the growing step by using a grooved substrate on which the bulk boron doped diamond electrode is deposited. Alternatively, the plurality of grooves may be formed after the growing step.

The present inventors have found that a cost effective way to implement the present invention is to provide a method of manufacturing a bulk boron doped diamond electrode, the method comprising:
providing a bulk boron doped diamond electrode;
forming a pattern of carbon solvent metal over a surface of the bulk boron doped diamond electrode; and
heating whereby the carbon solvent metal dissolves underlying diamond to form grooves in the surface of the bulk boron doped electrode.

### BRIEF DESCRIPTION OF THE DRAWINGS

For a better understanding of the present invention and to show how the same may be carried into effect, embodiments of the present invention will now be described by way of example only with reference to the accompanying drawings, in which:

FIG. 1 illustrates the basic steps involved in manufacturing a diamond electrode according to an embodiment of the present invention;

FIG. 2 illustrates the surface of a diamond electrode according to an embodiment of the present invention; and

FIG. 3 illustrates a portion of an electrochemical device comprising two opposed bulk BDD electrodes according to an embodiment of the present invention.

### DETAILED DESCRIPTION OF CERTAIN EMBODIMENTS

The present inventors have recognized that the cost of bulk BDD electrodes needs to be greatly reduced and the cost of running them needs to be as low as possible (i.e. high electrical efficiency is required) if they are to find widespread applications in industrial applications. One way of reducing the cost of bulk BDD electrodes is to increase the surface area of the electrodes by forming grooves therein. For the same electrode cost, a grooved surface should enable the electrochemical cell to operate at a lower current density, thus increasing the electrical efficiency for the same amount of work done. In practice, a combination of reduced electrode cost and reduced operating cost will lead to an overall reduction in the cost of waste destruction, enhancing competitiveness.

The grooves are formed in a pattern. For example, the grooves may be aligned substantially parallel to one another and/or aligned substantially perpendicular to an edge of the bulk BBD electrode. For example, the grooves may be substantially evenly spaced to form a pattern of evenly spaced substantially parallel channels. By “substantially” parallel/perpendicular we mean to within 20°, 10°, 5°, 2° or less.

Each groove has a width in the range 1 μm to 1 mm. If the grooves are made too small, for example in the nanometer range, then gas bubbles can become trapped within the grooves. If the grooves are made too large, then the increase in surface area can be insufficient to yield the desired increase in current density. Exemplary electrodes have a groove width in the range: 10 μm to 500 μm; 20 μm to 100 μm; or 20 μm to 50 μm.

Each groove has a depth in the range 1 μm to 1 mm. If the grooves are made too deep then gas bubbles can become trapped within the grooves. If the grooves are made too shallow, then the increase in surface area can be insufficient to yield the desired increase in electrical efficiency. Exemplary electrodes have a groove depth in the range: 10 μm to 500 μm; 20 μm to 100 μm; or 20 μm to 50 μm.

An aspect ratio of each groove in terms of depth : width may be between: 1:1 and 7.5:1; 1:1 and 5:1; or 1:1 and 3:1. If the aspect ratio is too large, then gas bubbles can become trapped within the grooves. If the aspect ratio is too low, then the increase in surface area can be insufficient to yield the desired increase in electrical efficiency.

In addition to the above considerations, the grooves should not be so deep as to weaken the electrode to the point where mechanical failure may occur during use. As such, the grooves should be less than 75% or 50% of the total electrode thickness, more preferably in the range 5 to 30% or 10 to 20%.

The grooves may be distributed over a face of the electrode such that a grooved area covers at least 50% of the total area of the face. Furthermore, the grooves may be distributed over both major faces of a plate-like electrode. The grooved area should cover a sufficient portion of the electrode so as to yield a desired increase in surface area and thus electrical efficiency.

In arrangements which have grooves distributed over both major faces of a plate-like electrode, the relative alignment of the grooves on the two faces can affect the fracture behaviour of the electrode. As such, it may be advantageous to offset the grooves on one face relative to the grooves on an opposite face such that troughs and peaks are not aligned symmetrically. Furthermore, rather than providing the grooves in exact parallel alignment, it may be advantages to misaligning the grooves by at least 2°, 5°, 7°, 10°, 12°, or 15° so that the distribution of thin regions in the electrode is broken up. This may also have electrical benefits, since thinning of the electrode from both sides at the same point can change the impedance of the electrode locally.

Each groove may extend in a continuous manner across at least 50% of the electrode width (or length depending on the orientation of the electrode). For example, each groove may be open ended and extend from one edge of the bulk boron doped diamond electrode to an opposite edge of the bulk boron doped diamond electrode. Alternatively, a plurality of shorter grooves may extend across the electrode width/length such that a two dimensional array of columns and rows of grooves is provided.

The bulk boron doped diamond electrodes according to embodiments of the invention may be a variety of different shapes including polygonal shapes such as square, rectangular, or hexagonal, and curved shapes such as oval or circular. One preferred option is a circular disk as stress may otherwise build up at corners leading to cracking.

The grooves may extend to the periphery of the bulk boron doped diamond electrode. Such open-ended grooves can be advantageous to improve fluid flow and prevent gas being trapped in end regions of the grooves. Alternatively, a peripheral region of a major face in which grooves are provided may have no grooves. This can be advantageous for providing a mounting region for the electrode for the purposes of sealing and in order to minimize the risk of crack propagation from the edges of the electrode. If such closed-end grooves are provided, it may be advantageous to taper the end regions of the grooves to improve fluid flow into and out of the grooves, minimize gas entrapment in the end regions of the grooves, and avoid stress points which could lead to fracture.

Modifying the diamond surface needs to be done in a cost effective way since these electrodes are a relatively low margin product. In addition, the surface structures formed on the electrode surface should be configured to avoid gas-bubble build-up which reduces electrode efficiency during use.

While forming grooves in the surface of most materials might be considered relatively straight forward, it is far from trivial to form such structures in the surface of a bulk BDD electrode due to the extreme hardness of the diamond material. One possibility is to use plasma etching. It is known to use plasma etching to produce structures such as diffraction gratings in optical grade diamond. However, plasma etching is relatively expensive and is primarily used in electronic processing and/or over small areas only. As such, while it may be possible to implement embodiments of the present invention using plasma etching, this is not a particularly cost effective way of performing the present invention.

Another possibility would be to grow the boron doped diamond over a grooved substrate such that grooves are automatically formed in the boron doped diamond electrode without the need for any subsequent surface treatment. One problem with this approach is that it can be difficult to grow and detach a boron doped diamond electrode from a grooved substrate without damaging the diamond electrode. However, if the boron doped diamond electrode is carefully removed from the substrate so as to avoid damaging the electrode this method can be useful.

One possibility to avoid damaging the electrode during separation from the substrate is to grow the electrode on a grooved silicon substrate and then dissolve the silicon substrate to produce a free-standing grooved bulk boron doped diamond electrode. One potential problem with this approach is that the silicon substrates cannot be re-used and this can increase production costs. Accordingly, another approach is to lift off the bulk boron doped diamond electrode from a grooved substrate which can then subsequently be re-used. Examples of suitable substrates include niobium, molybdenum, tungsten, alloys such as niobium, molybdenum and/or tungsten containing alloys, silicon carbide, silicon, and various ceramics. A difference in thermal expansion coefficient between the diamond material and the substrate material can be used to cause the electrode to automatically release from the substrate on cooling after deposition of the diamond material. In this regard, the thickness of the substrate and the electrode can be selected for a particular substrate material to achieve a suitable strain during cooling thereby triggering release of the electrode from the substrate. However, careful control is required to avoid cracking of the electrode.

The grooves may have a substantially square or rectangular cross-sectional shape. However, it is envisaged that other shapes may be provided such as substantially v-shaped grooves or curved grooves such as substantially u-shaped grooves. The cross-sectional shape of the grooves may be selected to more readily detach the diamond material from the substrate in arrangements which use a grooved substrate to form the grooved diamond electrode. In this case, square or rectangular cross-sectional shapes can lead to stress build-up and cracking during cooling after growth of the diamond electrode on the substrate. As such, when utilizing a grooved substrate it is preferred to provide grooves which are substantially v-shaped or curved grooves such as substantially u-shaped grooves.

The present inventors have found that a cost effective way to implement the present invention is to provide a method of manufacturing a bulk boron doped diamond electrode, the method comprising:
providing a bulk boron doped diamond electrode;
forming a pattern of carbon solvent metal over a surface of the bulk boron doped diamond electrode;
heating whereby the carbon solvent metal dissolves underlying diamond to form grooves in the surface of the bulk boron doped electrode.

There are various possible ways of forming the pattern of carbon solvent metal. For example, a low cost imprint lithography technique can be used to create the desired pattern with a photo resist ink. A thin film of a carbon solvent metal (e.g. Fe, Ni, Cr, Cu, Co) can then be deposited via electro-deposition, PVD, CVD or other low cost, thin film deposition technique. The photoresist can be dissolved before or after the heating step. It if preferred to remove the photoresist after the heating step such that all of the metal and photoresist can be cleaned from the diamond surface at the same time to reveal the grooved surface.

A diamond film grown by a CVD process on a substrate and subsequently removed will tend to have a relatively rough top surface (or growth surface) and a relatively smooth bottom surface (or nucleation surface), the bottom surface corresponding to the surface which contacted the substrate. As previously described, a rough surface will comprise a random distribution and orientation of surface structure such as small nodules and pits. These randomly oriented surface structures can trap and hold gas bubbles on the surface of the electrode in use. Accordingly, it can be advantageous to process at least the relatively rough growth surface of the diamond electrode to reduce its roughness before or after forming the grooves in accordance with the present invention. The surface of the electrode may be processed to reduce roughness using standard techniques such as grinding, polishing, etching, and/or lapping. The nucleation surface may also be treated to reduce roughness if required and/or the substrate pre-treated to ensure that the nucleation surface is smooth. The bulk boron doped diamond electrode thus may comprise at least one major surface, optionally two opposing major surfaces, having a surface roughness Ra in the range: 10 nm to 100 μm; 10 nm to 20 μm; 10 nm to 5 μm; 0.1 μm to 5 μm; 1 μm to 5 μm; 0.1 μm to 1 μm; or 10 nm to 30 nm. Mechanical lapping can be used to reduce Ra to as low as 0.1 μm and fine polishing can be used to reduce Ra down to 10 nm.

Surface roughness may be measured using a surface profilometer. It should be noted that the surface roughness values discussed above do not include the grooves. That is, the surface roughness measurements are not taken across the plurality of grooves.

In addition to reducing the volume of gas trapped on the surface of the bulk boron doped diamond electrode in use, a reduction in surface roughness is advantageous in that smaller grooves can be more precisely formed on a smooth surface using, for example, lithographic techniques. As such, reducing the surface roughness of the bulk boron doped diamond prior to formation of the grooves can allow a fine structure of grooves to be formed on the surface. A large increase in the active surface area of the electrode due to the grooves can thus be achieved and a large improvement in the performance of the electrode in use. For example, to achieve sub-micron lithography resolution a surface roughness Ra<30 nm is advantageous. Another important aspect for very high resolution lithography is flatness across the electrode. For example, to achieve sub-micron resolution for the grooves a flatness less that 20 μm is advantageous.

Once formed, the grooved bulk BDD electrodes can be introduced into an electrochemical device. The electrode may by oriented within the device such that the grooves are aligned in a direction substantially parallel to the direction of electrolyte flow. As previously described, this can enhance fluid flow within the channels/grooves and thus remove any bubbles attached to the surface of the electrode during operation of the device.

In intermittent or low flow applications, the grooves may be oriented substantially vertically to use gravitational assistance in removing bubbles. The fluid flow past the electrodes can also be arranged in a substantially vertical direction in order to align gravity and the flow forces.

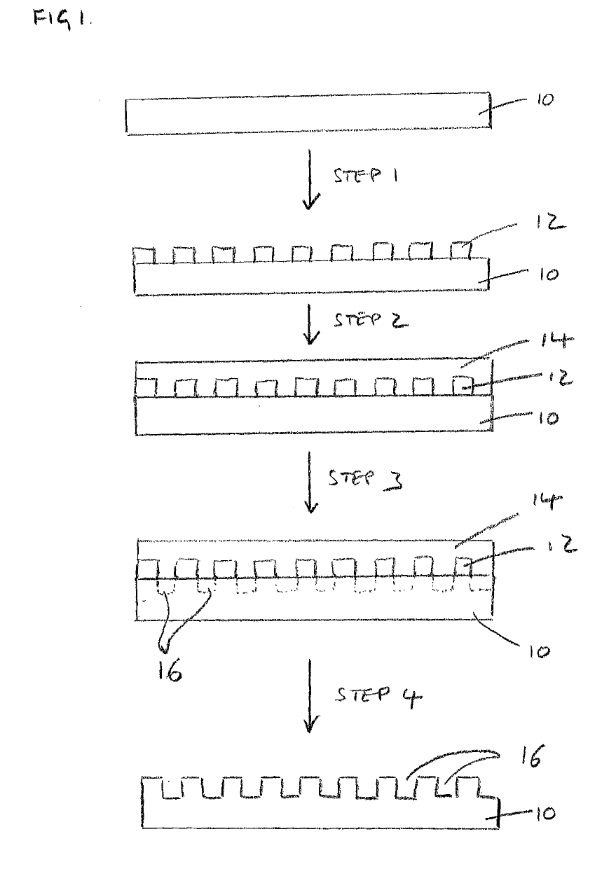

FIG. 1 illustrates the steps involved in performing the method according to one embodiment of the present invention. This method provides a technique for forming grooves in the surface of a bulk BDD electrode in a cost effective manner. The method starts with a boron doped diamond wafer 10.

In Step 1, a low cost imprint lithography technique is used to create a desired pattern with a photo-resist ink 12.

In Step 2, a thin film of a carbon solvent metal 14 (e.g. Fe, Ni, Cr, Cu, Co) is deposited via electro-deposition, physical vapour deposition (PVD), chemical vapour deposition (CVD), or other low cost thin film deposition technique.

In Step 3, the diamond electrode 10 is heated to approximately 600 to 650° C. to allow the metal 14 to dissolve the diamond electrode, resulting in a series of etched trenches 16 that mirror the original pattern.

In Step 4, the photo-resist and carbon solvent metal is removed to reveal the grooved surface 16 on the bulk boron doped diamond electrode 10. Suitable etching solutions are strongly oxidizing such as acid mixtures, for example: H₂SO₄/KNO₃; HF/HNO₃; or HCl/HNO₃.

The thickness of the metal layer together with the heating/oxidation time in Step 3 will determine the depth of the etching in the trenches. It is estimated that the costs of completing the method steps illustrated in FIG. 1 would be less than 10% of the manufacturing costs of the electrodes. This technique can lead to a performance gain equal to or greater than: 25%; 50%; 100%; 200%; 300%; 400% or even 500% depending on the dimensions of the grooves and the associated increase in effective surface area of the bulk BDD electrodes.

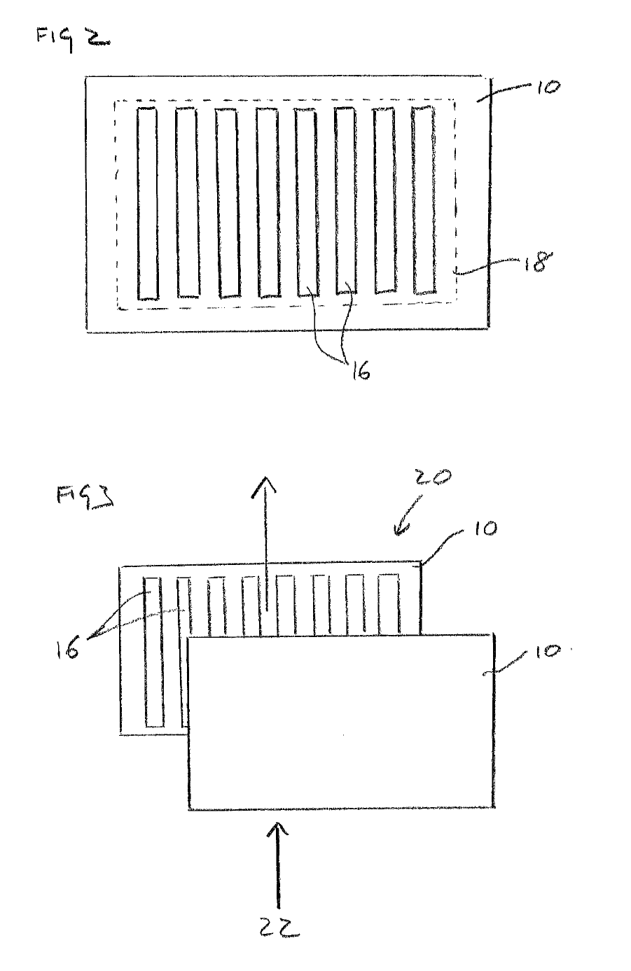

FIG. 2 illustrates the surface of a diamond electrode according to an embodiment of the present invention. The bulk boron doped diamond electrode 10 has an array of grooves 16 disposed over its surface in a grooved area 18 with a peripheral region having no grooves. Of course in certain embodiments the grooves 16 can extend from one edge of the diamond electrode to an opposite edge to form an open channel across the entire height/width of the electrode. Alternatively still, a two dimensional array of shorter grooves can be provided. Indeed, it is evident that this technique can be used to form a variety of patterns on a polycrystalline diamond surface as desired.

FIG. 3 illustrates a portion of an electrochemical device 20 comprising two opposed bulk BDD electrodes 10 according to an embodiment of the present invention. In the device, the grooves 16 are oriented so as to be disposed in a direction substantially parallel to the electrolyte flow direction 22.

Embodiments of the invention are particularly beneficial in bipolar electrode configurations. The electrochemical device may have a plurality of grooved electrodes in a face-to-face configuration with fluid flowing therebetween.

Embodiments of the present invention can increase the effective area of a bulk BDD electrode for less than 10% of the manufacturing costs. The macro scale structuring described herein can be used in conjunction with additional micro or nano scale structuring to increase the effective electrode area yet further. As an alternative route, or in combination with making the bulk BDD electrodes thinner, this is a very effective method of reducing diamond costs.

It is to be noted that this approach does not work in thin film diamond, where deposition of a conformal coating on a pre-structured surface is more applicable. However, bulk diamond electrodes are much more robust with a much greater dimensional stability and the present invention may extend the cost effectiveness of bulk BDD into low current density applications, such as water purification. These areas are currently seen as the domain of coated BDD electrodes.

While this invention has been particularly shown and described with reference to preferred embodiments, it will be understood to those skilled in the art that various changes in form and detail may be made without departing from the scope of the invention as defined by the appendant claims.

1. A bulk boron doped diamond electrode comprising a plurality of grooves disposed in a surface of the bulk boron doped diamond electrode, wherein the plurality of grooves are arranged in a pattern, wherein each groove forms a continuous channel, and wherein each groove has a width in the range 1 μm to 1 mm and a depth in the range 1 μm to 1 mm, wherein the plurality of grooves are aligned substantially parallel to one another to within 20° or less, and wherein the bulk boron doped diamond electrode is formed of a solid piece of boron doped diamond material rather than a diamond coated electrode which comprises a non-diamond core material over which a coating of diamond is disposed.

2-4. (canceled)

5. A bulk boron doped diamond electrode according to claim 1, wherein each groove has a width in the range: 10 μm to 500 μm; preferably 20 μm to 100 μm; or preferably 20 μm to 50 μm.

6. A bulk boron doped diamond electrode according to claim 1, wherein each groove has a depth in the range: 10 μm to 500 μm; preferably 20 μm to 100 μm; or preferably 20 μm to 50 μpm.

7. A bulk boron doped diamond electrode according to claim 1, wherein an aspect ratio of each groove in terms of depth: width is between: 1:1 and 7.5:1; 1:1 and 5:1; or 1:1 and 3:1.

8. A bulk boron doped diamond electrode according to any claim 1, wherein each groove has a depth meeting one or more of the following characteristics: the depth is less than 75% of a total electrode thickness, the depth is less than 50% of a total electrode thickness; the depth lies in a range 5 to 30% of a total electrode thickness; and the depth lies in a range 10 to 20% of a total electrode thickness.

9. (canceled)

10. A bulk boron doped diamond electrode according to claim 1, wherein the plurality of grooves are distributed over a face of the bulk boron doped diamond electrode such that a grooved area covers at least 50% of a total area of the face.

11. A bulk boron doped diamond electrode according to claim 1, wherein each groove extends in a continuous manner across at least 50% of an electrode width.

12-13. (canceled)

14. A bulk boron doped diamond electrode according to claim 1, wherein the grooves are distributed over both major faces of a plate-like bulk boron doped diamond electrode.

15. A method of manufacturing a bulk boron doped diamond electrode according to any preceding claim, the method comprising:
growing a bulk boron doped diamond electrode using a chemical vapour deposition technique; and
forming a plurality of grooves in a surface of the bulk boron doped diamond electrode.

16. A method according to claim 15, wherein the plurality of grooves are formed during the growing step by using a grooved substrate on which the bulk boron doped diamond electrode is deposited.

17. A method according to claim 15, wherein the plurality of grooves are formed after the growing step.

18. A method according to claim 17, wherein the plurality of grooves are formed by:
forming a pattern of carbon solvent metal over a surface of the bulk boron doped diamond electrode; and
heating whereby the carbon solvent metal dissolves underlying diamond to form grooves in the surface of the bulk boron doped diamond electrode.

19. A method according to claim 18, wherein forming a pattern of carbon solvent metal comprises forming a patterned mask over the bulk boron doped diamond electrode and depositing the carbon solvent metal through the mask.

20-23. (canceled)

24. An electrochemical device comprising a bulk boron doped diamond electrode according to claim 1.

25. An electrochemical device according to claim 24, wherein the bulk boron doped diamond electrode is oriented within the electrochemical device such that the grooves are aligned in a direction substantially parallel to a direction of electrolyte flow.

26. An electrochemical device according to claim 24, wherein a plurality of the bulk boron doped diamond electrodes are provided in a face-to-face configuration, each electrode configured to function as a bipolar electrode.
